(19) United States
(12) Patent Application Publication
(10) Pub. No.: US 2014/0035612 A1
(43) Pub. Date: Feb. 6, 2014

(54) Method and Measuring Device for Determining a State of a Semiconductor Material of a Chemosensitive Field-Effect Transistor that has been Tested and Delivered by a Manufacturer

(71) Applicant: Robert Bosch GmbH, Stuttgart (DE)

(72) Inventor: Stefan Noll, Stuttgart (DE)

(73) Assignee: Robert Bosch GmbH, Stuttgart (DE)

(21) Appl. No.: 13/955,427

(22) Filed: Jul. 31, 2013

(30) Foreign Application Priority Data
Aug. 1, 2012 (DE) 10 2012 213 530.8

(51) Int. Cl. G01R 31/26

(52) U.S. Cl. CPC G01R 31/2621
USPC 324/762.09

(57) ABSTRACT

The disclosure relates to a method for determining a state of a semiconductor material of a chemosensitive field-effect transistor that has been tested and delivered by a manufacturer. The chemosensitive field-effect transistor includes a source contact, a drain contact, a gate contact of a chemosensitive gate electrode, and a substrate contact. The method includes applying a voltage between the gate contact and a reference potential to the field-effect transistor that has been tested and delivered by the manufacturer. The method further includes detecting a current between the source contact and the substrate contact, and determining the state using the voltage and the current.

This application claims priority under 35 U.S.C. §119 to patent application no. DE 10 2012 213 530.8, filed on Aug. 1, 2012 in Germany, the disclosure of which is incorporated herein by reference in its entirety.

### BACKGROUND

The present disclosure relates to a method for determining a state of a semiconductor material of a chemosensitive field-effect transistor that has been tested and delivered by a manufacturer, a corresponding measuring device, and a corresponding computer program product.

DE 10 2009 045 475 A1 depicts a gas-sensitive semiconductor device.

### SUMMARY

In this context, the present disclosure provides a method for determining a state of a semiconductor material of a delivered chemosensitive field-effect transistor, a corresponding measuring device, and finally, a corresponding computer program product according to the main claims. Advantageous embodiments result from the particular dependent claims and the description below. The chemosensitive field-effect transistor is a finished chemosensitive field-effect transistor that has been tested by a manufacturer. In other words, the field-effect transistor is not only housed and/or packaged, but testing on it has already been completed.

A chemosensitive field-effect transistor has a transfer characteristic. The transfer characteristic represents a relationship between an applied operating voltage in combination with a concentration of a chemical species on a sensor surface of the field-effect transistor and a resulting current flow through the field-effect transistor. The transfer characteristic can be changed if the chemical species or another chemical species, for example, changes electrical characteristics of a semiconductor material of the field-effect transistor initially tested and delivered by a manufacturer.

The disclosure is based on the knowledge that it is possible to assess a state of the semiconductor material based on a resulting current flow between a source electrode and a bulk electrode when applying a voltage between the bulk electrode and a gate electrode. Based on the identified state, the transfer characteristic can be adapted in order to obtain useful information about the concentration of the species to be measured, even if the characteristics of the semiconductor material are modified.

The present disclosure provides a method for determining a state of a semiconductor material of a chemosensitive field-effect transistor that has been tested and delivered by a manufacturer, wherein the chemosensitive field-effect transistor has a source contact, a drain contact, a gate contact of a chemosensitive gate electrode, and a substrate contact, wherein the method is carried out after completion of a test process of the chemosensitive field-effect transistor, wherein the manufacturing process of the chemosensitive field-effect transistor is already completed, and wherein the method (200) has the following steps:

Application of a measuring signal between the gate contact and a reference potential to the field-effect transistor that has been tested and delivered by the manufacturer;

Detection of a current between the source contact and the substrate contact; and

Determination of the state using the voltage and the current.

A chemosensitive field-effect transistor that has been tested and delivered by a manufacturer can presently be understood to be a voltage-controlled transistor that is already tested and ready for operation, in which a current flow through a channel between a source electrode and a drain electrode is controlled via a voltage that is applied between the source electrode and a gate electrode. A quantity of ions accumulated at the gate electrode of a fluid component of a fluid is in an equilibrium with a partial pressure or a concentration of the fluid component in the fluid. The quantity of the ions determines a carrier concentration in the gate electrode. The carrier concentration causes an electric field to form at the gate electrode. The electric field influences a conductivity of the channel via an attraction or repulsion of charge carriers in the semiconductor substrate. A substrate contact can be situated on a side of the transistor situated opposite the gate electrode, and can be attached to the semiconductor substrate. An application of a measuring signal can be understood to be a connection of the contact to a voltage source, or to a source that generates a voltage signal that is varied with respect to time. The ground can be understood to be a potential-free region. Detection can be understood to be measuring and/or tapping the current flow. A value of the current or the current itself can be used in the step of determination. A value of the voltage or the voltage itself can be used in the step of determination. The state can be determined using a processing specification. A processing specification can be understood to be a specification in which the current and the voltage values, and if applicable, other values, can be linked to each other in order to perform an assessment of the state of the semiconductor material. Such a state can be understood, for example, a specific saturation of the semiconductor material, in particular, of the substrate of the field-effect transistor with a certain material, which, for example, is diffused from the fluid into the substrate via the gate electrode. Alternatively, the state to be determined can also be understood to be a local, partially reversible or even irreversible change in the conductivity via the effect of the material from the fluid in the substrate. In addition, gas species or reaction products of gas species can diffuse from the surrounding gas atmosphere into the substrate via the gate electrode. Their presence either in or at the gate electrode, in the gate insulator, or in the substrate can likewise have an effect on the conductivity of the component.

The measuring signal can be applied as a voltage pulse that has a rising edge having a specified rise with respect to time from a first voltage value to a second voltage value. Alternatively or in addition, the voltage pulse can have a falling edge having a specified drop with respect to time from the second voltage value to the first voltage value. A rise with respect to time or a drop with respect to time can be understood to be a rise or a drop of the voltage by a predefined voltage value within a predefined time period. By raising the voltage in a controlled manner or by dropping the voltage in a controlled manner, the current can be detected if an electric field generated by the voltage between the gate electrode and the substrate contact is just strong enough to induce a current flow. This makes it possible to correlate the voltage value to a current value of the current. The voltage values can be positive and/or negative. The edges can each have a zero crossing. For example, the rising edge of a negative voltage value can rise to a positive voltage value and in doing so have a voltage of zero volts at the zero crossing. For example, the trailing edge of a positive voltage value can drop to a negative voltage value and in doing so have another zero crossing.

The voltage can have a specified first dwell time at the first voltage value. Alternatively or additionally, the voltage can have a specified second dwell time at the second voltage value. Specified dwell times at the extreme values make it possible to evaluate effects that can be detected during a rising edge separately from effects that can be detected during a falling edge. The edges can also have plateaus in order to determine the state of the semiconductor material in smaller voltage steps.

In the step of application, it is possible to apply at least one additional voltage pulse. In the step of detection, it is possible to detect at least one additional current. By repeating the measurement, it is possible to detect a change in the state with respect to a previous measurement. This makes it possible to detect a change in the state of the semiconductor material periodically.

The additional voltage pulse can has a predefined rise with respect to time from a third voltage value differing from the first voltage value to a fourth voltage value differing from the second voltage value, and/or the additional voltage pulse can have a third dwell time at the third voltage value differing from the first dwell time and/or a fourth dwell time at the fourth voltage value differing from the second dwell time. It is possible to determine different characteristics or states of the semiconductor material by means of different minimum and/or maximum voltage values. If a voltage difference between the two voltage values is smaller than required to move charge carriers in the instantaneous state of the semiconductor material, it can be determined that the required voltage is instantaneously larger than the voltage difference between the two voltage values.

The additional voltage pulse can have a pulse shape that is changed with respect to the voltage pulse, than the voltage pulse. For example, the edges can have different shapes. For example, one edge can run linearly and one edge can have a sinusoidally rising or falling shape. Flatter and/or steeper edge ranges make it possible to traverse voltage ranges more quickly or more slowly in order, for example, to be able to detect or skip delayed changes in the current. In the step of detection, it is possible to detect a time characteristic of the current, wherein the characteristic is detected at least over one period of the application of the voltage. A characteristic makes it possible to detect transitional states in the semiconductor material that are able to be identified due to state changes in the semiconductor material.

The method can have a step of connecting a drain contact of the field-effect transistor to the source contact, wherein the drain contact is directly connected to the source contact. Connecting makes it possible to place the source contact and the drain contact at an identical potential. Connecting can be understood to be short-circuiting or connecting to a measuring instrument that behaves like a short circuit.

The method can have a step of disconnecting a supply voltage, in which the source contact is disconnected from a first output of a voltage source, and in which the drain contact is disconnected from a second output of the voltage source. The voltage source can provide a supply voltage that is required for operating the transistor. Disconnecting can be used to take the transistor out of operation.

The method can have a step that is performed before the step of application of measuring a measurand, wherein the measurand is measured while applying a supply voltage between the source contact and the drain contact, as well as a voltage potential applied to the gate electrode, wherein the measurand represents a concentration of at least one fluid component of the fluid. The method can have an additional step to be carried out after the step of determination of measuring the measurand. The measurand can be the current flow through the channel between the source electrode and the drain electrode. By alternately measuring and determining the state, an operating point of the transistor can be reliably determined and a value of the measurand can be accordingly corrected. This makes it possible to determine the concentration reliably.

The present disclosure furthermore provides a measuring device for determining a state of a semiconductor material of a chemosensitive field-effect transistor that has been tested and delivered by a manufacturer, the material being designed to perform and implement the steps of the method according to the disclosure in corresponding devices. This embodiment of the disclosure in the form of a device also makes it possible to achieve the object underlying the disclosure quickly and efficiently.

A measuring device can presently be understood to be an electrical device that processes signals and outputs control and/or data signals as a function of the signals. The measuring device can have at least one interface, which can be a hardware- and/or software-based design. In a hardware-based design, the interfaces can, for example, be part of a so-called system ASIC that includes a wide variety of functions of the measuring device. However, it is also possible for the interfaces to be stand-alone, integrated circuits or to consist at least partially of discrete components. In a software-based design, the interfaces can be software modules that, for example, are present on a microcontroller in addition to other software modules.

A computer program product having programming code is also advantageous, the code being able to be stored on a machine-readable medium such as a semiconductor memory, a hard-disk memory, or an optical memory, and being used to carry out the method according to one of the previous embodiments if the program product is implemented on a computer or a device.

### BRIEF DESCRIPTION OF THE DRAWINGS

The disclosure is described in detail by way of example below using the included drawings. The following are shown:

FIG. 1 A block diagram of a measuring device according to an embodiment of the present disclosure;

FIG. 2 A flow diagram of a method for determining a state of a semiconductor material of a chemosensitive field-effect transistor according to an embodiment of the present disclosure;

FIG. 3 A diagram of a voltage-time characteristic of a voltage pulse according to an embodiment of the present disclosure;

FIG. 4 A diagram of a current-time characteristic of a detected current flow according to an embodiment of the present disclosure;

FIG. 5 A representation of state changes of atoms in a semiconductor material during a voltage pulse according to an embodiment of the present disclosure; and

FIG. 6 A representation of a characteristic map of a semiconductor sensor, which was recorded while it was acted upon by a plurality of different voltage pulses according to embodiments of the present disclosure.

### DETAILED DESCRIPTION

In the following description of preferred embodiments of the present disclosure, identical or similar reference numbers are used for the elements that are represented in the various figures and act similarly, thus avoiding a repeated description of these elements.

FIG. 1 shows a block diagram of a measuring device 100 according to an embodiment of the present disclosure. The measuring device 100 has a device for application 102, a device for detection 104, and a device for determination 106. The measuring device 100 is designed to determine a state of a semiconductor material 108, which has been tested and delivered by a manufacturer, of a chemosensitive field-effect transistor 110. The chemosensitive field-effect transistor 110 has a source electrode 112, a drain electrode 114, a chemosensitive gate electrode 116, and a substrate electrode 118. The gate electrode 116 is electrically insulated from the semiconductor material 108 via an insulating layer 120. The insulating layer 120 can also be chemically sensitive. The gate electrode 116 can then be simply electroconductive (if applicable, also porous). The chemosensitive field-effect transistor 110 is acted upon by a gas flow. The device for application 102 is connected to a ground contact 122, which has a reference potential, and the gate electrode 116. The device for application 102 is designed to apply a voltage as a measurement parameter between the gate contact 116 and the ground contact 122. The device for application 102 can be a pulse generator or an oscillator. The device for detection 104 is connected to the substrate electrode 118 and the source electrode 112. The device for detection 104 is designed to detect a current between the source contact 112 and the substrate contact 118 as measurement information. The connection line between the source contact 112 and the device for detection 104 is connected to the ground contact 122. The device for determination 106 is connected to the device for application 102 and the device for determination 104.

The device for determination 106 designed to determine the state of the semiconductor material 108 using the voltage and the current. The chemosensitive field-effect transistor 110 has a separate base-bulk contact 118 with connected current measurement 104.

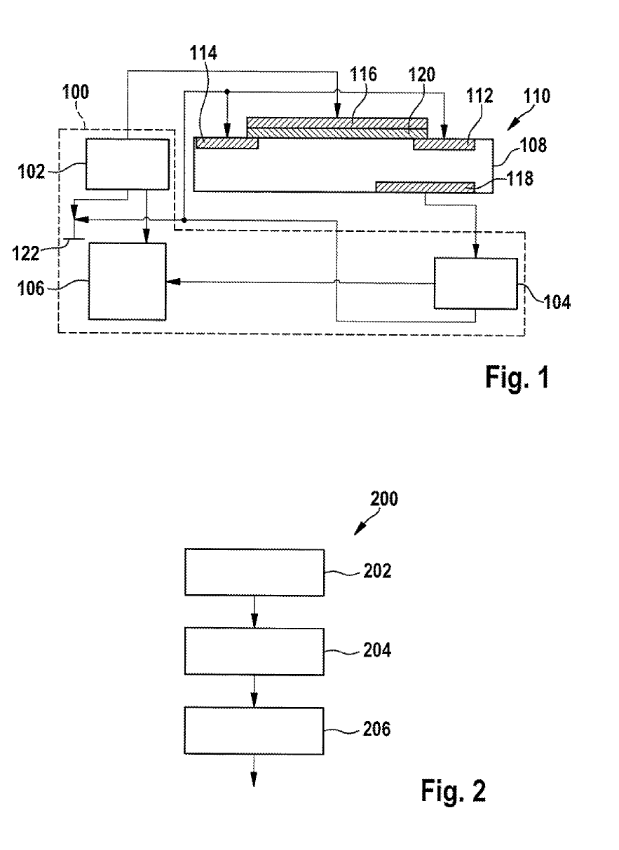

FIG. 2 shows a flow diagram of a method 200 for determining a state of a semiconductor material of a chemosensitive field-effect transistor that has been tested and delivered by a manufacturer according to an embodiment of the present disclosure. The method 200 has a step of application 202, a step of detection 204, and a step of determination 206. The method 200 can be performed in a measuring device (106) as shown in FIG. 1. In the step 202 of application, a voltage is applied between a gate contact of the field-effect transistor that has been tested and delivered by a manufacturer and a ground contact. In the step 204 of detection, a current is detected between a source contact of the field-effect transistor and a substrate contact of the field-effect transistor. In the step 206 of determination, the state is determined using the voltage and the current.

In other words, FIG. 2 shows a method 200 for evaluating a chemically sensitive transistor using a charge pumping method. Charge pumping is a characterizing method for assessing the semiconductor-insulator boundary. The method 200 can be used for process control and process assessment and can be used in the finished product or during operation.

Applying gas to a chemically sensitive transistor changes the physical properties of the gate, including the existing impurities. The charge pumping method 200 measures these changes and provides additional information about the gases to be measured. The transfer characteristic of the transistor is normally used in the finished product for assessing the change caused by the application of gas. The influence of the impurities on the transfer characteristic is generally not taken into account.

The charge pumping method 200 measures the impurities directly. Unlike other direct impurity assessment methods, it can also be used directly in the product because of its simplicity. A fundamental idea of the method 200 is to pulse a transistor in accumulation and inversion and to measure the flow of recombination current during this process in order to detect external influences.

The charge pumping method 200 detects only the influence of impurities. The capture of static charges at the gate electrode does not influence the charge pumping measurement result or does so only in a secondary manner. It is thus possible to separate the concentration-related signals that are normally detected on the transistor from influences due to the gas interaction. The method 200 can be used with all semiconductor-based sensors having a transistor, particularly in semiconductor-based gas sensors having a transistor.

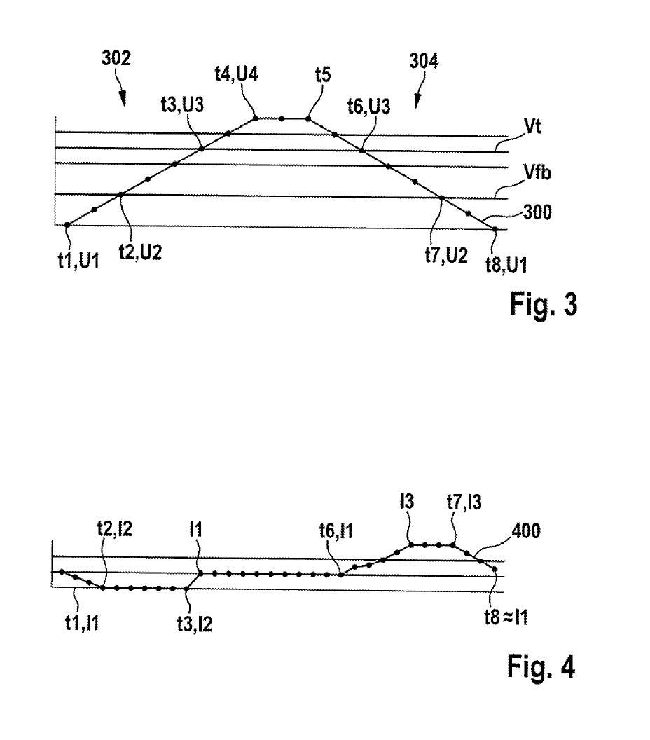

FIG. 3 shows a diagram of a voltage-time characteristic of a voltage pulse 300 according to an embodiment of the present disclosure, which is applied to the gate electrode, for example, by the measuring device in FIG. 1. A continuous period of time is plotted on the abscissa of the diagram. A voltage between a gate contact and a source contact of a chemosensitive field-effect transistor as shown in FIG. 1 is plotted on the ordinate of the diagram. The voltage pulse 300 begins at an instant t1 at a first voltage value U1. The voltage pulse 300 has a rising edge 302 having a specified rise. At an instant t2, the voltage pulse 300 has a voltage U2 and exceeds a flat-band voltage Vfb. At an instant t3, the voltage pulse 300 has a voltage U3 and exceeds the threshold voltage VT. At an instant t4, the voltage pulse 300 has a second voltage value U4. The rising edge 302 in this embodiment has a constant slope between the first voltage value U1 and the second voltage value U4. Starting from the instant t4, the second voltage value U4 remains constant up to an instant t5. A dwell time t4 to t5 at the second voltage value U4 is specified. Starting at the instant t5, the voltage pulse 300 has a falling edge 304 having another specified slope or time-related drop. At an instant t6, the voltage pulse 300 has the voltage U3 and falls below the threshold voltage VT. At an instant t7, the voltage pulse 300 has the voltage U2 and falls below the flat-band voltage Vfb. At an instant t8, the voltage pulse 300 has the first voltage value U1. Between the second voltage value U4 and the first voltage value U1, the falling edge 304 in this embodiment has a constant slope. In other words, FIG. 3 shows a pulse shape of the voltage applied at the gate electrode.

For example, the first voltage value U1 can be minus four volts. The flat-band voltage Vfb can be minus two volts. The threshold voltage VT can be one point two volts. The second voltage value U4 can be three volts. At instant t1, zero time units can have elapsed. At instant t2, two time units can have elapsed. At instant t3, five time units can have elapsed. At instant t4, seven time units can have elapsed. At instant t5, 93 time units can have elapsed. At instant t6, 95 time units can have elapsed. At instant t7, 98 time units can have elapsed. At instant t8, 100 time units can have elapsed.

FIG. 4 shows a diagram of a current-time characteristic of a detected current flow 400 according to an embodiment of the present disclosure. A continuous period of time is plotted on the abscissa of the diagram, as in FIG. 3. The same period is represented in FIG. 3 and FIG. 4. A value of a current between a source contact and a substrate contact of a chemosensitive field-effect transistor as shown in FIG. 1 is plotted on the ordinate of the diagram. The current flow 400 begins at an instant t1 at a current value I1. After instant t1, the current flow 400 falls at an approximately constant slope. At instant t2, the current flow 400 has a current value I2. Up to instant t3, the current flow 400 remains constant at the current value I2. After instant t3, the current flow 400 increases rapidly to the current value I1 and then remains at the current value I1 until just prior to instant t6. After instant t6, the current flow increases to a current value I3. Between the current value I1 and the current value I3, the current flow 300 has a rising edge, which initially has a steep slope, then flattens out, and finally becomes steeper again. At the current value I3, the current value remains constant until approximately instant t7. After instant t7, the current flow 400 falls until instant t8 from the current value I3 to just above the current value I1. In other words, FIG. 4 shows a charge pumping current flow Icp 400.

For example, the current value I1 can be zero amperes. The current value I2 can be minus one ampere. The current value I3 can be two amperes.

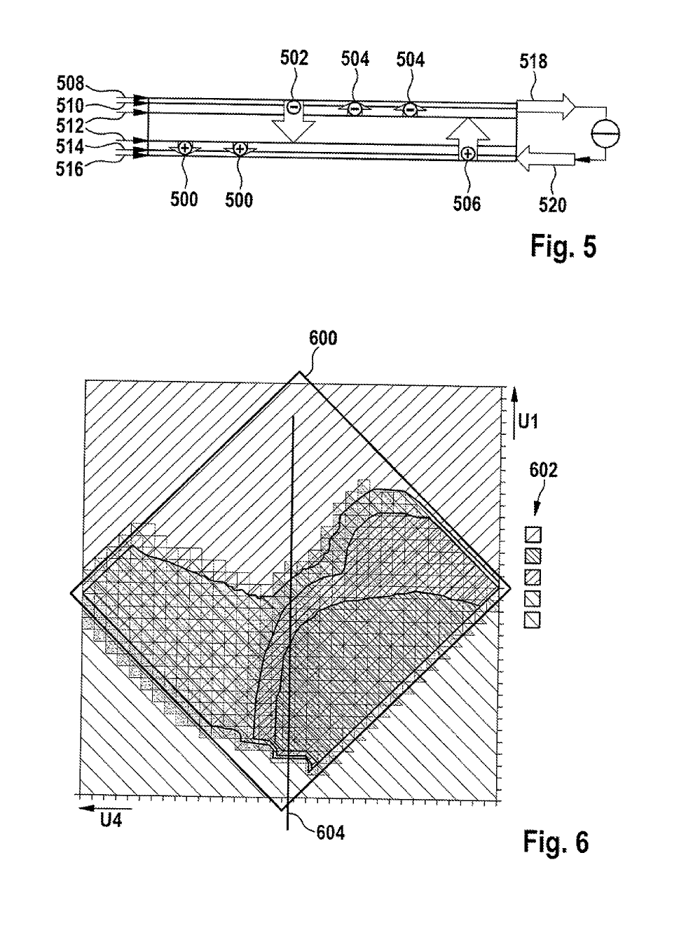

FIG. 5 shows a representation of state changes 500, 502, 504, 506 of atoms of a semiconductor material during a voltage pulse according to an embodiment of the present disclosure. The atoms have different energy levels 508, 510, 512, 514, 516 in different states. Specific voltage potentials are associated with the energy levels. If the voltage applied in the step of application is larger than a difference in potential between two energy levels, charge carriers are released and result in a current flow 518, 520 in the semiconductor material. FIG. 5 depicts band ranges of the current flow.

In other words, FIGS. 3, 4, and 5 show a charge pumping pulse 300, the resulting current flow 400; 518, 520 and the underlying state changes using the band model. At the start of the pulse 300, the transistor is in accumulation; in other words, the Fermi level lies close to the valence band, as shown in FIG. 5. The external voltage rises and the Fermi level moves upward. In doing so, the interface traps or impurities are correspondingly charged. At the start of the pulse 300, the charge is still neutralized fast enough. However, the compensation rate is quickly no longer sufficient, and the semiconductor goes into a thermodynamically unstable state.

As soon as the threshold voltage VT has been reached, an inversion channel forms, and the carrier concentration increases in the conduction band. The traps (impurities) can then be charged with an opposing charge from the conduction band.

On the falling edge 304, the traps/impurities again begin to discharge. The discharge process initially goes in the direction of the conduction band. However, after once again falling below the threshold voltage VT, the discharge occurs in the direction of the valence band.

The charging and discharging of different bands takes place due to the corresponding time constants of the traps/impurities. By contacting the bands to different electrodes (source, drain contacts and bulk contact), a current 400; 518, 520 flows between the two electrodes. This current is finally denoted as charge pumping current 400. The characteristic of the flowing current is shown in FIG. 4.

The corresponding charging and discharging currents are marked in FIG. 5 in a band diagram. The corresponding band ranges that are transferred and which cause the charge pumping current 400 are illustrated.

With each pulse, a certain quantity of charge carriers flows through the ammeter. In the first approximation, the current is thus proportional to the applied frequency.

Depending on the pulse shape used, the range in which the impurities are transferred can be varied. Differing edge slopes restrict the energy range. Likewise, it is possible, for example, to use three different voltage levels to restrict the selection of the active impurities.

FIG. 6 shows a diagram of a characteristic map of a semiconductor sensor, which was captured using a plurality of different voltage pulses according to multiple embodiments of the present disclosure. In this embodiment, the semiconductor sensor is a silicon carbide transistor. On the ordinate of the diagram, a first voltage value U1 is plotted as represented in FIG. 3. On the abscissa, a second voltage value U4 is plotted as represented in FIG. 3. In this embodiment, the first voltage value U1 is plotted as V_{low} in range from −16.5 volts to 0.5 volts, while the second voltage value U4 is plotted as V_{high} in a range from −6 volts to 11.5 volts. A legend 602 is shown beside the diagram that depicts five different current value ranges of the resulting current flow (bulk current) when changing from U1 to U4 in a logarithmic gradation from 10⁻¹⁶ amperes to 1.5⁻⁸ amperes. A first current value range has values between 1.5·10⁻⁸ amperes and 1.0·10⁻⁸. A second current value range has values between 1.0·10⁻⁸ amperes and 1.0·10⁻¹⁰. A third current value range has values between 1.5·10⁻¹⁰ amperes and 1.0·10⁻¹². A fourth current value range has values between 1.5·10⁻¹² amperes and 1.0·10⁻¹⁴. A fifth current value range has values between 1.5·10⁻¹⁴ amperes and 1.0·10⁻¹⁶. In the diagram, a value of a current value measured by the device 104 from one of the above ranges is assigned to each value pair formed by a first voltage value U1 and a second voltage value U4 and is depicted according to the legend. Doing this results in ranges surfaces having identical current value ranges. A measuring range 600 of the sensor is depicted within the characteristic map. The ranges are entered in the diagram as surfaces having different designs.

A first triangular area without current flow is depicted for small first voltage values U1 and small second voltage values U4. Likewise, a second triangular area without current flow is depicted for small first voltage values U1 and large second voltage values. A third triangular area without current flow is depicted for large first voltage values U1 and large second voltage values U4. Likewise, a fourth triangular area without current flow is depicted for large first voltage values U1 and small second voltage values U4. The measuring range 600 is depicted as an area in which a current flow has predominantly been detected. The measuring range 600 has a rectangular shape whose straight edges are aligned diagonally along the areas without current flow. A line 604 is entered in the measuring range 600, which represents an application point 604. The line 604 is aligned parallel to the ordinate and runs through two opposite corners of the measuring range 600. In this embodiment, the application point 604 is at a second voltage value U4 of 3 volts. No current flow occurs outside the measuring range 600. Likewise, no current flow appears at an upper point of the measuring range 600, in the range of large first voltage values U1 and medium second voltage values U4.

The embodiments described and shown in the figures are chosen only as examples. It is possible to combine different embodiments completely or with respect to individual characteristics. An embodiment can also be supplemented by characteristics of another embodiment.

Furthermore, method steps according to the disclosure can be implemented repeatedly and in a sequence other than that described.

If an embodiment includes an “and/or” link between a first characteristic and a second characteristic, this is to be read in such a way that the embodiment has both the first characteristic and the second characteristic according to one specific embodiment and has either only the first characteristic or only the second characteristic according to another specific embodiment.

What is claimed is:

1. A method for determining a state of a semiconductor material of a chemosensitive field-effect transistor, the chemosensitive field-effect transistor including a source contact, a drain contact, a gate contact of a chemosensitive gate electrode, and a substrate contact, the method comprising:
applying a voltage between the gate contact and a reference potential to the field-effect transistor;
detecting of a current between the source contact and the substrate contact; and
determining the state using the voltage and the current,
wherein the method is carried out after completion of a test process of the chemosensitive field-effect transistor, and
wherein a manufacturing process of the chemosensitive field-effect transistor is already completed.

2. The method according to claim 1, wherein:
the voltage is applied as a voltage pulse, and
the voltage pulse includes at least one of (i) a rising edge having a specified rise with respect to time from a first voltage value to a second voltage value, and (ii) a falling edge having a specified drop with respect to time from the second voltage value to the first voltage value.

3. The method according to claim 2, wherein in the applying the voltage, the voltage has at least one of (i) a specified first dwell time at the first voltage value, and (ii) a specified second dwell time at the second voltage value.

4. The method according to claim 2, wherein the applying the voltage includes applying at least one additional voltage pulse.

5. The method according to claim 4, wherein:
the additional voltage pulse has a predefined rise with respect to time from a third voltage value differing from the first voltage value to a fourth voltage value differing from the second voltage value, and/or
the additional voltage pulse has a third dwell time at the third voltage value differing from the first dwell time and/or a fourth dwell time at the fourth voltage value differing from the second dwell time.

6. The method according to claim 4, wherein the additional voltage pulse has a pulse shape that is changed with respect to the voltage pulse.

7. The method according to claim 4, wherein:
the detection further includes detecting a time characteristic of the current, and
the time characteristic is detected at least over one period of the application of the voltage.

8. The method according to claim 1, further comprising:
connecting a drain contact of the field-effect transistor to the source contact,
wherein the drain contact is directly connected to the source contact.

9. The method according to claim 1, further comprising:
disconnecting a supply voltage,
wherein the disconnecting includes (i) disconnecting the source contact from a first output of a voltage source, and (ii) disconnecting the drain contact from a second output of the voltage source.

10. The method according to claim 9, further comprising:
measuring a measurand while applying (i) the supply voltage between the source contact and the drain contact, and (ii) a voltage potential to the gate electrode,
wherein a step is performed before the measuring the measurand, and
wherein the measurand represents a concentration of at least one fluid component of the fluid.

11. The method according to claim 10, wherein an additional step is carried out after the measuring the measurand.

12. A measuring device for determining a state of a semiconductor material of a chemosensitive field-effect transistor, the chemosensitive field-effect transistor including a source contact, a drain contact, a gate contact of a chemosensitive gate electrode, and a substrate contact, the measuring device comprising:
a voltage unit configured to apply a voltage between the gate contact and a reference potential to the field-effect transistor;
a detection unit configured to detect a current between the source contact and the substrate contact; and
a determining unit configured to determine the state using the voltage and the current,
wherein the state is determined after completion of a test process of the chemosensitive field-effect transistor, and
wherein a manufacturing process of the chemosensitive field-effect transistor is already completed.

13. A computer program product comprising:
a memory unit configured to store a programming code for activating or implementing a method for determining a state of a semiconductor material of a chemosensitive field-effect transistor, if the computer program product is implemented on a device or a measuring device,
wherein the chemosensitive field-effect transistor includes a source contact, a drain contact, a gate contact of a chemosensitive gate electrode, and a substrate contact,
wherein the method includes
applying a voltage between the gate contact and a reference potential to the field-effect transistor,
detecting a current between the source contact and the substrate contact, and
determining the state using the voltage and the current,
wherein the method is carried out after completion of a test process of the chemosensitive field-effect transistor, and
wherein a manufacturing process of the chemosensitive field-effect transistor is already completed.
